(19) United States
(12) Patent Application Publication
(10) Pub. No.: US 2024/0351841 A1
(43) Pub. Date: Oct. 24, 2024

(54) MOUNTING BAR CONNECTION SYSTEM

(71) Applicant: HERC BUILD LLC, Bonita Springs, FL (US)

(72) Inventors: Brian DWIGHT, Lindsay (CA); Craig PRATT, Whitchurch-Stouffville (CA); David DWIGHT, Pickering (CA)

(21) Appl. No.: 18/640,587

(22) Filed: Apr. 19, 2024

Related U.S. Application Data
(60) Provisional application No. 63/461,195, filed on Apr. 21, 2023.

(51) Int. Cl. B66F 11/04

(52) U.S. Cl. CPC B66F 11/044

(57) ABSTRACT

The present disclosure relates to a mounting bar connection system including a receiver assembly containing (a) a receiver top plate comprising a top surface, a bottom surface, and a plurality of holes passing through the top plate; (b) a receiver bottom plate having a top surface, a bottom surface, and a plurality of holes configured to line up with the holes of the top plate; (c) at least one through bolt configured to pass through at least one hole of the top plate and one hole of the bottom plate and to secure the top plate and the bottom plate to each other; and (d) two side plates extending away from the bottom surface of the receiver bottom plate in a parallel plane to each other, the two side plates having a plurality of holes that at least partially align with each other.

### CROSS-REFERENCE SECTION

This Application claims priority to U.S. Provisional Application No. 63/461,195, filed on Apr. 21, 2023, which is incorporated by reference herein in its entirety for all purposes.

### FIELD OF THE DISCLOSURE

This application relates to a mounting connection system providing for quick connection and disconnection of a truss, an auxiliary mounting bar, or both on to a telescopic/aerial work platform.

### BACKGROUND

Aerial work platforms containing light fixtures are used in the film, concert, stage, theatrical, architectural, trade show, commercial, and construction industries. The light fixtures are generally mounted on aerial work platforms so they can be strategically located at elevated positions to illuminate specific areas. However, safely attaching light fixtures to commercial aerial work platforms is often arduous due to a lack of standardized couplers.

There is presently a need for an engineered and load rated solution that is simple to install which results in a complete and safe mounting connection system by virtue of compatibility (everything fits correctly without guess work). Further, there is need for an apparatus that facilitates the rapid exchange of components related to connecting work platforms to lighting fixtures and trusses.

### SUMMARY

One aspect of the disclosed subject matter relates to a truss/auxiliary mounting bar connection system for connecting an aerial work platform to a truss or auxiliary mounting bar. The truss/auxiliary mounting bar connection system may include a receiver assembly configured to secure to a floor of the platform. The receiver assembly may include a receiver top plate including a top surface, a bottom surface, and a plurality of holes configured to each receive one of a plurality of bolts. The receiver assembly may include a receiver bottom plate including a top surface, a bottom surface, and a plurality of holes configured to each receive the one of the plurality of bolts, wherein the receiver assembly is configured to secure a floor of the platform in between the bottom surface of the receiver top plate and the top surface of the receiver bottom plate and to fasten the securement with at least one bolt fastening the top plate to the bottom plate while securing the platform. The receiver assembly may include two parallel side plates extending away from the bottom surface of the receiver bottom plate, the two parallel side plates including a plurality of holes configured to couple to at least one of an upright arm and a truss mounting bracket. The receiver assembly may include the upright arm. The upright arm may include a top end including a mount top tube lock configured to fasten to a top member. The upright arm may include two rotating adjustable clamping mechanisms, which accommodates several pipe arrangements and sizes. The upright arm may include lower mounting plate that contains provisions to accept industry standard pipe to be used as an additional accessory attachment point. The upright arm may include a bottom end including a clevis pin configured to fasten to at least one of the plurality of holes of each of the two parallel side plates. The upright arm may include an elongated shaft connecting the top end and the bottom end and including a truss mounting bracket configured to attach to a rail of the platform. The receiver assembly may include the truss mounting bracket. The truss mounting bracket may include a cylindrical elongate body and two wings extending in a parallel direction from the body and configured to each separately couple, with a pin, to holes of each of the two parallel side plates. The receiver may include a clamp configured to secure the cylindrical elongate body to a truss.

The present disclosure relates to a mounting bar connection system. The mounting bar connection system may include a receiver assembly. The receiver assembly may include a receiver top plate comprising a top surface, a bottom surface, and a plurality of holes passing through the top plate. The receiver assembly may include a receiver bottom plate including (i) a top surface; (ii) a bottom surface; (iii) a plurality of holes configured to line up with the holes of the top plate; and (iv) two side plates extending away from the bottom surface in a parallel plane to each other, the two side plates comprising a plurality of holes that at least partially align with each other. The receiver assembly may include at least one through bolt configured to pass through at least one hole of the top plate and one hole of the bottom plate and to secure the top plate and the bottom plate to each other.

According to some embodiments, the present disclosure relates to a mounting bar connection system. The mounting bar connection system may include a receiver assembly. The receiver assembly may include (a) a receiver top plate including a top surface, a bottom surface, and a plurality of holes passing through the top plate. The receiver assembly may include (b) a first receiver bottom plate containing (i) a top surface, (ii) a bottom surface, (iii) a plurality of holes configured to line up with the holes of the top plate; and (iv) set of two side plates extending away from the bottom surface of the first receiver bottom plate in a parallel plane to each other, the set of two side plates comprising a plurality of holes that at least partially align with each other. The receiver assembly may include (c) a second receiver bottom plate including (i) a top surface, (ii) a bottom surface, (iii) a plurality of holes configured to line up with the holes of the top plate; and (iv) a set of two side plates extending away from the bottom surface of the second receiver bottom plate in a parallel plane to each other, the set of two side plates comprising a plurality of holes that at least partially align with each other. The receiver assembly may include (d) at least two through bolts configured to individually pass through at least one hole of the top plate and one hole of the first bottom plate and the second bottom plate.

In some embodiments, the present disclosure relates to a mounting bar connection system that includes a truss mounting bracket containing (i) a cylindrical elongate body; (ii) a first wing extending away from the body, the first wing comprising a hole at the end of the first wing and configured to couple to one of the holes of the side plates of the receiver assembly with a first pin; and (iii) a clamp configured to secure the cylindrical elongate body to part of a truss. The truss mounting bracket may include a second wing extending away from the body, where the second wing comprises a hole at the end of the second wing and is configured to couple to one of the holes of the side plates of the receiver assembly with a second pin. The truss mounting bracket may include a second clamp configured to secure the cylindrical elongate body to part of the truss.

A mounting bar connection system according to the present disclosure may include at least one throughbolt fitted through at least one hole of each of the side plates. The throughbolt may be configured to secure the side plates to an upright arm. The bottom surface of a top plate and a top surface of a bottom plate may be configured to surround a portion of a work platform. The throughbolt may be configured to secure a receiver assembly to the work platform when passed through at least one hole of the top plate and one hole of the bottom plate while the top plate and bottom plate surround the portion of the work platform. The mounting bar connection system may include an upright arm. The upright arm may include (a) an elongated shaft connecting a top end and a bottom end, the top end comprising a mount top tube lock; and (b) a lower mounting plate connected to the bottom end of the elongated shaft and extending away from the bottom end in a perpendicular direction. The lower mounting plate may include (i) at least one hole configured to align with at least one hole of each of the side plates; and (ii) at least one throughbolt configured to fit through the holes of the lower mounting plate and each of the side plates. The upright arm may include (c) a top member fitted through the mount top tube lock of the top end of the elongated shaft.

A mounting bar connection system according to the present disclosure may include a second upright arm. The second upright arm may include (a) an elongated shaft connecting a top end and a bottom end, the top end comprising a mount top tube lock; and (b) a lower mounting plate connected to the bottom end of the elongated shaft and extending away from the bottom end in a perpendicular direction. The lower mounting plate may include (i) at least one hole configured to align with at least one hole of each of the side plates; and (ii) at least one throughbolt configured to fit through the holes of the lower mounting plate and each of the side plates. In some embodiments, the top member may fit through the top lock of the second upright arm. The upright arm may include at least one clamping mechanism having a hook and an attachment mechanism that secures to a portion of the elongated shaft of the upright arm. The clamping mechanism may be configured to secure the upright arm to a portion of a work platform. The upright arm may include a spigot. The spigot may include a frame having an outside surface and an inside surface configured to wrap around an outside surface of the top member and a threaded fastener configured to secure the frame to the top member.

### BRIEF DESCRIPTION OF THE DRAWINGS

The disclosure is illustrated by way of example, and not by way of limitation, in the figures of the accompanying drawings in which like reference numerals are used to refer to similar elements. It is emphasized that various features may not be drawn to scale, and the dimensions of various features may be arbitrarily increased or reduced for clarity of discussion.

FIG. 1 illustrates a side perspective of a disclosed mounting bar connection system connected to an aerial work platform using the auxiliary mounting bar to support a light fixture, according to some embodiments of the disclosure.

FIG. 2A illustrates a side perspective of a disclosed mounting bar connection system receiver assembly bolted onto a work platform, according to some embodiments of the disclosure.

FIG. 2B illustrates a zoomed in view of the side perspective of the disclosed mounting bar connection of FIG. 2A, according to some embodiments of the disclosure.

FIG. 3A illustrates a side perspective of a mounting bar connection system receiver assembly having one receiver bottom plate, according to some embodiments of the disclosure.

FIG. 3B illustrates a side perspective of a mounting bar connection system receiver assembly having two receiver bottom plates, according to some embodiments of the disclosure.

FIG. 4A illustrates a side perspective of a receiver assembly and an upright arm of a disclosed mounting bar connection system connected to a work platform, according to some embodiments of the disclosure.

FIG. 4B illustrates a zoomed in view of the side perspective of the receive assembly and the upright arm of the disclosed mounting bar of FIG. 4A, according to some embodiments of the disclosure.

FIG. 5A illustrates a side perspective of two upright arms and a top member of a disclosed mounting bar connection system, according to some embodiments of the disclosure.

FIG. 5B illustrates a side perspective of an upright arm with a spigot and a mount top tube lock, according to some embodiments of the disclosure.

FIG. 6 illustrates a side perspective of a work platform fitted with the mounting bar connection system, supporting a box truss and under slung light fixtures, according to some embodiments of the disclosure.

FIG. 7A illustrates a side perspective of a work platform fitted with the mounting bar connection system, supporting a box truss using the included truss brackets, according to some embodiments of the disclosure.

FIG. 7B illustrates a zoomed in view of the side perspective of the work platform as shown in FIG. 7A, according to some embodiments of the disclosure.

FIG. 8 illustrates a side perspective of a truss mounting bracket assembly, according to some embodiments of the disclosure.

### DETAILED DESCRIPTION

The present disclosure relates to a mounting bar connection system that provides for a quick connection and disconnection of various components associated with elevated lighting structures. For example, the disclosed mounting bar connection system may permit quick connection to and disconnection from light fixtures, work platforms (e.g., aerial work platforms), trusses, and telescopic handlers (e.g., telescopic forklifts). Disclosed mounting bar connection systems include a receiver assembly, an upright arm, and a truss mounting bracket that advantageously function to safely and quickly let a user set up or take down known elevated lighting structures. Additionally, disclosed mounting bar connection systems can readily couple to commercial and otherwise known elevated lighting structures without the need of additional couplers, safety straps, and out of the ordinary tools.

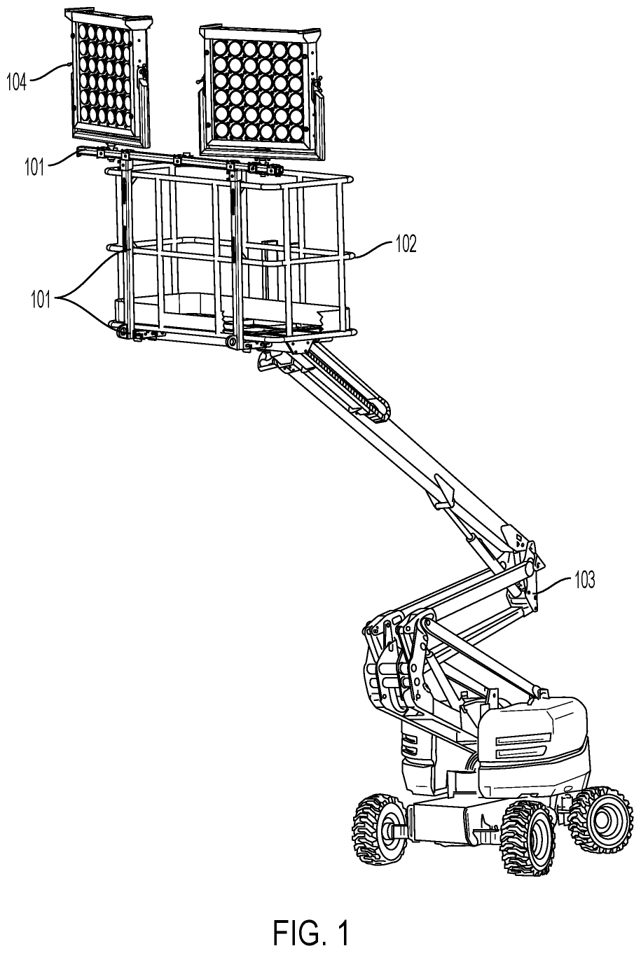

FIG. 1 shows a disclosed mounting bar connection system 101 connecting a light fixture 104 to a work platform 102 as well as connecting the work platform 102 to a telescopic handler 103. The mounting bar connection system 101 may connect each of the work platform 102, the telescopic handler 103, and the light fixture 104 to each other in any combination quickly, safely, and without required additional connectors or safety components. Each component of the disclosed mounting bar connection system 101 may include load rated attachment points to provide for safe and quick connection and disconnection between each of the work platform 102, the telescopic handler 103, and the light fixture 104. In some embodiments, each of the components of the disclosed mounting bar connection system 101 may be adjusted to various lengths, widths, and heights as to accommodate known work platforms 102 (e.g., aerial work platform), known light fixtures 104, known telescopic handlers 103, and other accessories known in the art.

### Receiver Assembly

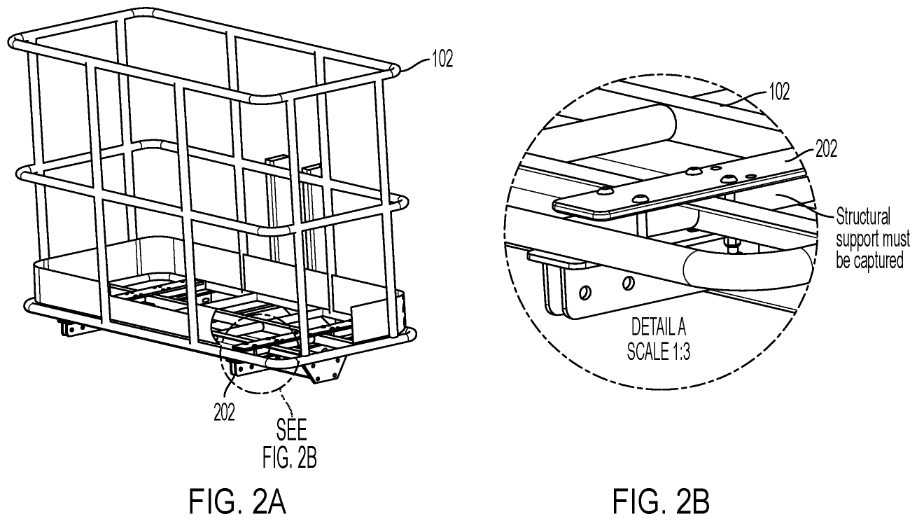

A disclosed mounting bar connection system 101 may include a receiver assembly that may directly connect to various parts of a work platform 102. FIGS. 2A & 2B illustrate a side perspective of the receiver assembly 202 connected to a bottom of the work platform 102. FIG. 2B specifically illustrates a zoomed in view of the receiver assembly 202 of FIG. 2A. In some embodiments, as shown in FIGS. 2A & 2B, the receiver assembly 202 may be bolted onto the floor of the work platform 102 with through bolts and nuts.

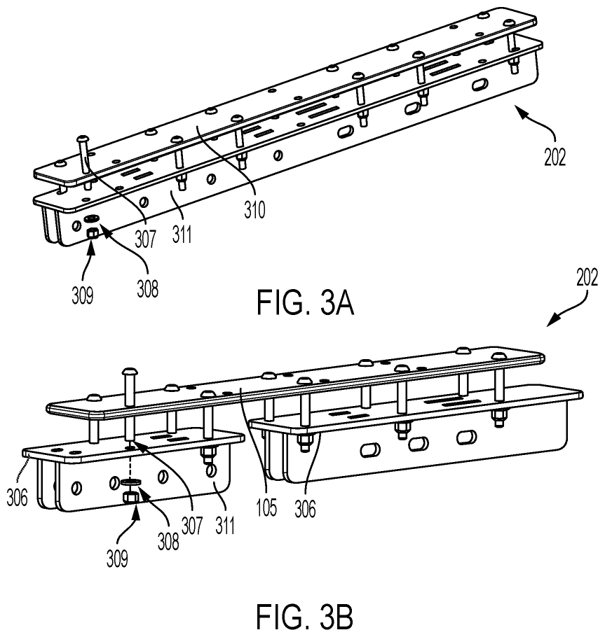

FIGS. 3A-3B illustrate multiple embodiments of a receiver assembly 202. As shown in FIG. 3A, the receiver assembly may include a receiver top plate 310 having a top surface, a bottom surface, and a plurality of holes passing through the top plate 310. The receiver assembly may include a receiver bottom plate 306 having a top surface, a bottom surface, and a plurality of holes configured to align with the holes of the top plate 310. The top plate 310 and the bottom plate 306 may be fastened together with bolts 307, washers 308, and nuts 309. As shown in FIG. 3A, both the top plate 310 and the bottom plate 306 may have a number of holes, such as ranging from about 1 hole to about 20 holes, or more. For example, each of the top plate 310 and the bottom plate 306 may have about 1 hole, or about 2 holes, or about 4 holes, or about 6 holes, or about 8 holes, or about 10 holes, or about 12 holes, or about 14 holes, or about 16 holes, or about 18 holes, or about 20 holes, or more, where about includes plus or minus 1 hole. Each of the holes of the top plate 310 and the bottom plate 306 may be fastened together using any number of bolts 307, washers 308, nuts 309, or other known fasteners. The receiver assembly 202 may be configured to capture a structural floor member of a work platform (not shown) in between the bottom surface of the receiver top plate 310 and the top surface of the receiver bottom plate 306. In some embodiments, a bolt may be used to fasten the receiver top plate 310 to the receiver bottom plate 306 and thus secure the work platform between the plates, establishing a connection between the components.

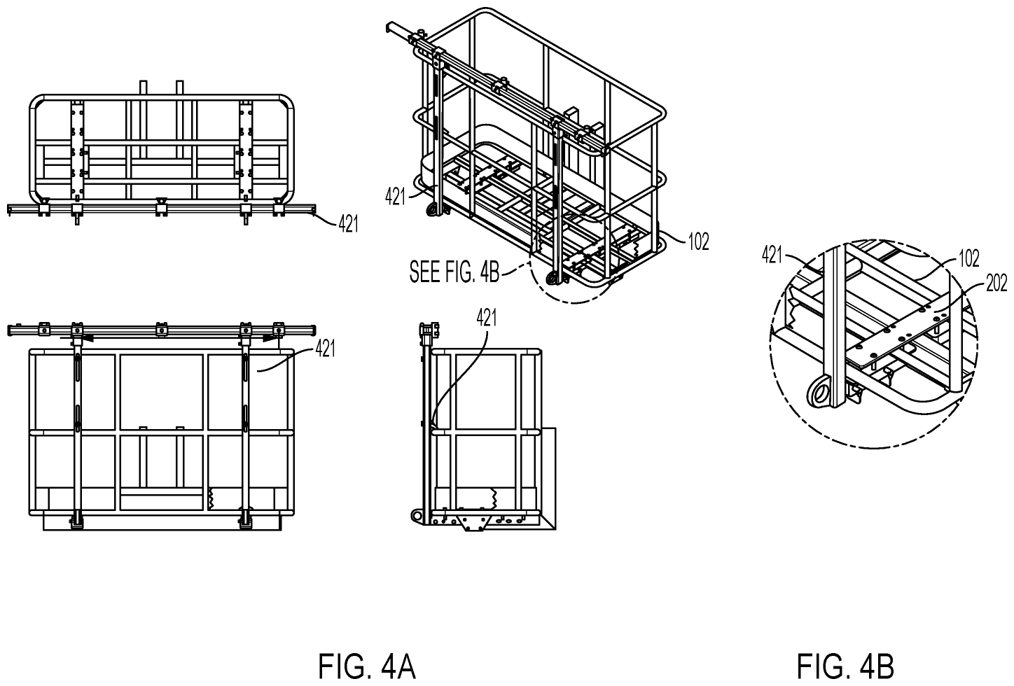

As shown in FIG. 3A, a bottom plate 306 may include two side plates 311 extending away from a bottom surface of the bottom plate 306. The side plates 311 may extend away from the bottom surface of the bottom plate 306 in a parallel plane to each other. The side plates 311 may include a plurality of aligned holes. The side plates 311 may include from about 2 holes to about 20 holes. For example, the side plates 311 may include about 2 holes, or about 4 holes, or about 6 holes, or about 8 holes, or about 10 holes, or about 12 holes, or about 14 holes, or about 16 holes, or about 18 holes, or about 20 holes, or more, where about includes plus or minus 1 hole. The side plate 311 holes may be configured to secure a receiver assembly 202 to other mounting bar connection system 101 components, including a lower mounting plate of an upright arm (See FIG. 4) using any number of connectors, including pins and bolts (not shown).

FIG. 3B shows a receiver assembly 202 having two receiver bottom plates 311. While FIG. 3B shows the receiver assembly 202 having 2 receiver bottom plates 311, the receiver assembly 202 may have any number of bottom plates 311. For example, the receiver assembly 202 may have about 2 bottom plates 311, or about 3 bottom plates 311, or about 4 bottom plates 311, or about 5 bottom plates 311, or about 6 bottom plates 311, or about 7 bottom plates 311, or about 8 bottom plates 311, or about 9 bottom plates 311, or about 10 bottom plates 311, or more, where about includes plus or minus 1 bottom plate.

Components of a receiver assembly 202 may be made from any metal (e.g., steel) or polymer (e.g., polyethylene). The receiver assembly 202 may be made of a polymer including a polyethylene, a polystyrene, a polyurethane, a nylon, a polypropylene, a polyethylene terephthalate, a polymethylmethacrylate, a polyacrylonitrile, a polyvinyl chloride, a polycarbonate, a silicone, a polyester, mixtures thereof, and copolymers thereof. The receiver assembly 202 may be made of a metal including a steel, a titanium, a brass, a copper, a lead, an iron, a bronze, an aluminum, a carbon steel, mixtures thereof, and alloys thereof. Components of the receiver assembly 202 may have any general size, such as having at least one dimension (e.g., length, width, height, diameter, etc.) that is about 1 inch, or about 2 inches, or about 3 inches, or about 4 inches, or about 5 inches, or about 6 inches, or about 7 inches, or about 8 inches, or about 9 inches, or about 10 inches, or about 11 inches, or about 12 inches, or more, where about includes plus or minus 1 inch. Components of the receiver assembly 202 may have any general size, such as having at least one dimension (e.g., length, width, height, diameter, etc.) that is about 1 foot, or about 2 feet, or about 3 feet, or about 4 feet, or about 5 feet, or about 6 feet, or about 7 feet, or about 8 feet, or about 9 feet, or about 10 feet, or about 11 feet, or about 12 feet, or more, where about includes plus or minus 1 foot.

### Upright Arm

A disclosed mounting bar connection system 101 may include an upright arm that may directly connect to various parts of a work platform 102. As is shown in FIGS. 4A & 4B, the disclosed mounting bar connection system 101 may include an upright arm 421 that connects to at least one of a receiver assembly 202 and a work platform 102. FIG. 4B is a zoomed in view of FIG. 4A. In some embodiments, the mounting bar connection system 101 may include more than one upright arm 421 for connecting to more than one receiver assembly 202. The number of upright arms 421 and receiver assemblies 202 may be adjusted to fit the needs of different sizes of work platforms 102. For example, the mounting bar connection system 101 may include about 1 upright arm 421, or about 2 upright arms 421, or about 3 upright arms 421, or about 4 upright arms 421, or about 5 upright arms 421, or about 6 upright arms 421, or about 7 upright arms 421, or about 8 upright arms 421, or about 9 upright arms 421, or about 10 upright arms 421, where about includes plus or minus 1 upright arm 421.

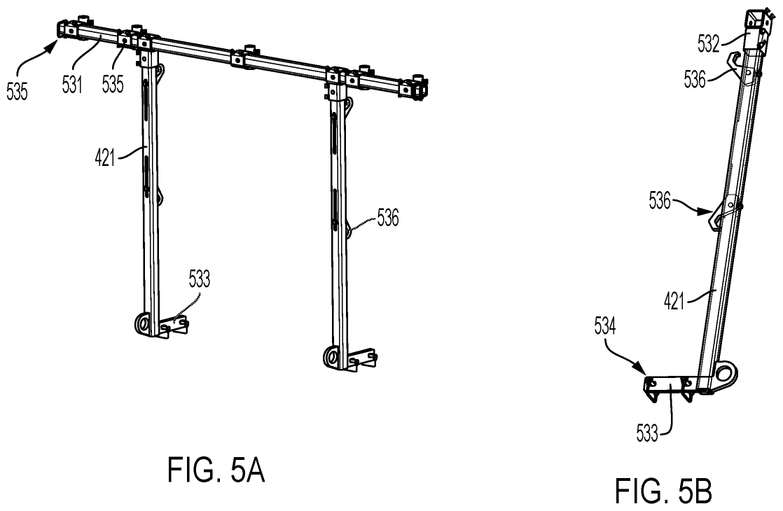

FIG. 5A shows two upright arms 421 engaging with a top member 531. Each upright arm 421 may include an elongated shaft connecting a top end to a bottom end. The top end may include a mount top tube lock 532. The mount top tube lock 532 may include an opening configured to receive the top member 531 and attach to the top end of the upright arm 421 to connect the upright arm 421 to the top member 531. Each upright arm 421 may include a lower mounting plate 533 extending away from the bottom end of the upright arm 421. The lower mounting plate 533 may extend away from the bottom end in a perpendicular direction so that the lower mounting plate 533 and the bottom end orient in an about 90-degree angle with respect to each other. The lower mounting plate 533 may include at least one hole configured to align with a hole of each side plate of a receiver assembly (see 202 from FIG. 2). In some embodiments, a fastener (e.g., throughbolt, clevis pin) may be configured to fit through the holes of the lower mounting plate 533 and holes found in each of the side plates, thereby securing the lower mounting plate 533 to the side plates. Securing the lower mounting plate 533 to the side plates may secure the upright arm 421 to the receiver assembly. The lower mounting plate 533 may have any number of holes, such as from about 1 hole to about 10 holes, or more. For example, the lower mounting plate 533 may include about 1 hole, or about 2 holes, or about 4 holes, or about 6 holes, or about 8 holes, or about 10 holes, or more, where about includes plus or minus 1 hole.

As shown in FIG. 5A, an upright arm 421 may engage with a top member 531. The top member may be fitted through a mount top tube lock 532 of a top end of the upright arm 421. The top member 531 may include an elongated shaft configured to serve as a support for any kind of light fixture or to attach to any part of a work platform (See 102 from FIG. 1). The top member 531 may include any number of spigots 535 configured to slide along any part of the top member 531 and be secured into position, ready to couple of any known light fixture. The spigot 535 may include a frame having an outside surface and an inside surface configured to wrap around an outside surface of the top member. The spigot 535 may include a threaded fastener configured to secure the frame of the spigot 535 to the top member 531. In some embodiments, the spigot 535 may include any known type of fastener, including a spring-loaded fastener.

According to some embodiments, as shown in FIG. 5B, an upright arm 421 may include a clamping mechanism 536. The clamping mechanism 536 may secure the upright arm 421 to any part of a work platform, such as any beam, connector, or railing. The clamping mechanism 536 may also attach to any part of a truss, including any beam, connector pole, or railing. The clamping mechanism 536 may fit inside of the upright arm at various positions and include a hook shaped body. The clamping mechanism 536 may be spring loaded, as to clamp around a structure using spring tension to form a part of the attachment. The clamping mechanism 536 may also incorporate any number of fasteners to attach to any structure. As shown in FIG. 5B, the hook of the clamping mechanism 536 may be oriented to face in multiple directions, such as being oriented towards a top end of the upright arm 421 or a bottom end of the upright arm 421. However, the hook of the clamping mechanism 536 may orient in any number of directions. The size of the hook may be adjusted to fit any known structure sizes and shapes.

Components of an upright arm 421 may be made from any metal (e.g., steel) or polymer (e.g., polyethylene). The upright arm 421 may be made of a polymer including a polyethylene, a polystyrene, a polyurethane, a nylon, a polypropylene, a polyethylene terephthalate, a polymethylmethacrylate, a polyacrylonitrile, a polyvinyl chloride, a polycarbonate, a silicone, a polyester, mixtures thereof, and copolymers thereof. The upright arm 421 may be made of a metal including a steel, a titanium, a brass, a copper, a lead, an iron, a bronze, an aluminum, a carbon steel, mixtures thereof, and alloys thereof. Components of the upright arm 421 may have any general size, such as having at least one dimension (e.g., length, width, height, diameter, etc.) that is about 1 inch, or about 2 inches, or about 3 inches, or about 4 inches, or about 5 inches, or about 6 inches, or about 7 inches, or about 8 inches, or about 9 inches, or about 10 inches, or about 11 inches, or about 12 inches, or more, where about includes plus or minus 1 inch. Components of the upright arm 421 may have any general size, such as having at least one dimension (e.g., length, width, height, diameter, etc.) that is about 1 foot, or about 2 feet, or about 3 feet, or about 4 feet, or about 5 feet, or about 6 feet, or about 7 feet, or about 8 feet, or about 9 feet, or about 10 feet, or about 11 feet, or about 12 feet, or more, where about includes plus or minus 1 foot.

### Truss Bracket Assembly

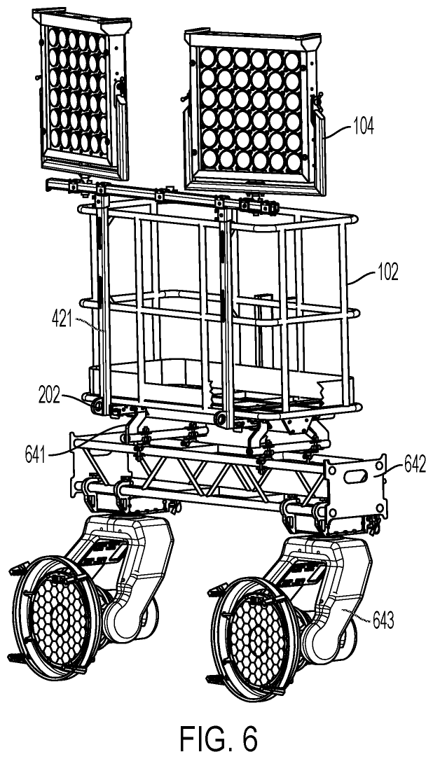

FIG. 6 illustrates a side perspective of a work platform 102 coupled to a receiver assembly 202, a truss bracket assembly 641, and an upright arm 421 supporting two light fixtures 104. FIG. 6 includes the truss bracket assembly 641 attached to a box truss 642 supporting under slung light fixtures 643. While the truss shown in FIG. 6 is depicted as being short in length, any truss or similar structure can be used while having a similar configuration. Similarly, the disclosed truss bracket assemblies 641 may be used to connect any disclosed receiver assembly 202 to any truss or similar structure. Additionally, while FIG. 6 shows two truss bracket assemblies 641, a disclosed mounting bar connection system may include any number of truss bracket assemblies 641 that may be used and fitted to any number or size of receiver assemblies and trusses. For example, the mounting bar connection system may include about 1 truss bracket assembly 641, or about 2 truss bracket assemblies, or about 4 truss bracket assemblies, or about 6 truss bracket assemblies, or about 8 truss bracket assemblies, or about 10 truss bracket assemblies, or more, where about includes plus or minus 1 truss bracket assembly.

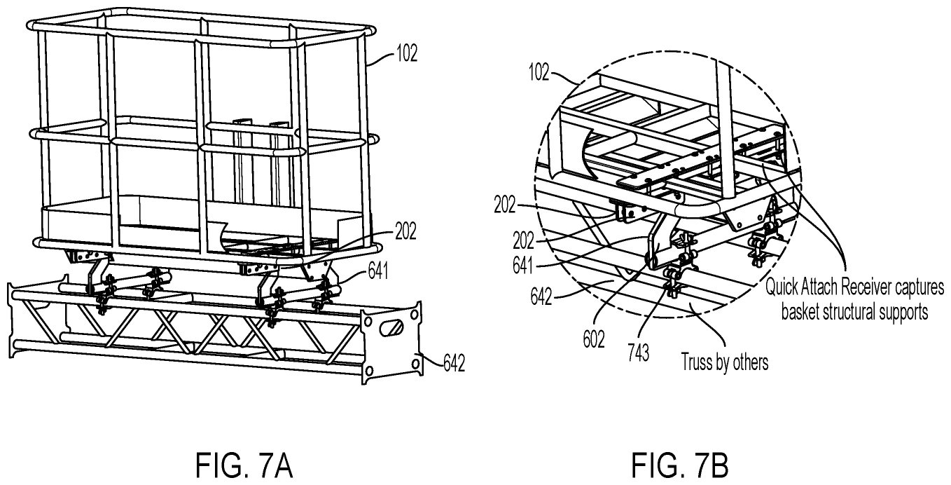

FIGS. 7A & 7B show a disclosed work platform 102 coupled to a receiver assembly 202 and a truss bracket assembly 641 that is coupled to a truss 642. FIG. 7B is a zoomed in view of FIG. 7A. As shown in FIGS. 7A & 7B, a truss bracket assembly 641 may include a clamp 743 configured to attach the truss bracket assembly 641 to the truss 642. The configuration shown in FIGS. 7A & 7B shows a mounting bar connection system having two truss bracket assemblies 641 that each have two clamps 743. However, each truss bracket assembly 641 may have any number of clamps 743, ranging from about 1 clamp to about 10 clamps, or more. For example, a truss bracket assembly may have 1 clamp 743, or about 2 clamps, or about 4 clamps, or about 6 clamps, or about 8 clamps, or about 10 clamps, or more, where about includes plus or minus clamp.

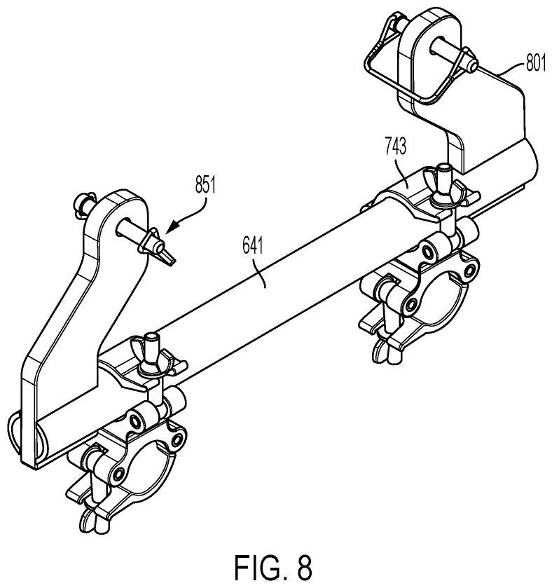

FIG. 8 shows a close-up view of a truss mounting bracket assembly 641. As shown in FIG. 8, the truss mounting bracket assembly 641 may include a cylindrical elongate body. However, other shapes may be incorporated. For example, instead of having a circular cross-section (i.e., cylindrical elongate body), the truss mounting bracket assembly 641 may have a cross-section including a square, a rectangle, a triangle, an oval, a diamond, any polygon, and more. The truss mounting bracket assembly 641 may include at least one wing 801 that extends away from the body. Each wing 801 may include a hole at the end of the wing. In some embodiments, the hole at the end of the wing may be configured to couple to any numbers of holes from a side plate of a receiver bottom plate (see 311 at FIG. 3). Any number of fasteners may secure the wing to the side plate by connecting and fastening the components through the holes found in each. For example, a pin 851 may slide through the holes of each of the wing 801 and the side plates so that the components are securely fastened together. FIG. 8 shows the truss mounting bracket assembly 641 having two wings, but the truss mounting bracket assembly 641 may have from 1 wing to 10 wings, or more. For example, the truss mounting bracket assembly 641 may have 1 wing 801, or about 2 wings, or about 4 wings, or about 6 wings, or about 8 wings, or about 10 wings, or more, where about includes plus or minus 1 wing. As described above, each truss mounting bracket assembly 641 may have any number of clamps 743. Additionally, each clamp 743 may vary in size to account for various sizes of trusses 642.

The figures and descriptions provided herein may have been simplified to illustrate aspects that are relevant for a clear understanding of the herein described devices, systems, and methods, while eliminating, for the purpose of clarity, other aspects that may be found in typical similar devices, systems, and methods. Those of ordinary skill may recognize that other elements and/or operations may be desirable and/or necessary to implement the devices, systems, and methods described herein. But because such elements and operations are well known in the art, and because they do not facilitate a better understanding of the present disclosure, a discussion of such elements and operations may not be provided herein. However, the present disclosure is deemed to inherently include all such elements, variations, and modifications to the described aspects that would be known to those of ordinary skill in the art.

The terminology used herein is for the purpose of describing particular example embodiments only and is not intended to be limiting. For example, as used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc., may be used herein to describe various elements, components, regions, layers and/or sections, these elements, components, regions, layers and/or sections should not be limited by these terms. These terms may be only used to distinguish one element, component, region, layer or section from another element, component, region, layer or section. That is, terms such as “first,” “second,” and other numerical terms, when used herein, do not imply a sequence or order unless clearly indicated by the context. Reference in the specification to “one implementation” or “an implementation” means that a particular feature, structure, or characteristic described in connection with the implementation is included in at least one implementation of the disclosure. The appearances of the phrase “in one implementation,” “in some implementations,” “in one instance,” “in some instances,” “in one case,” “in some cases,” “in one embodiment,” or “in some embodiments” in various places in the specification are not necessarily all referring to the same implementation or embodiment.

Finally, the above descriptions of the implementations of the present disclosure have been presented for the purposes of illustration and description. It is not intended to be exhaustive or to limit the present disclosure to the precise form disclosed. Many modifications and variations are possible in light of the above teaching. It is intended that the scope of the present disclosure be limited not by this detailed description, but rather by the claims of this application. As will be understood by those familiar with the art, the present disclosure may be embodied in other specific forms without departing from the spirit or essential characteristics thereof. Accordingly, the present disclosure is intended to be illustrative, but not limiting, of the scope of the present disclosure, which is set forth in the following claims.

What is claimed is:

1. A mounting bar connection system comprising:
a receiver assembly comprising:
(a) a receiver top plate comprising a top surface, a bottom surface, and a plurality of holes passing through the top plate;
(b) a receiver bottom plate comprising:
(i) a top surface;
(ii) a bottom surface;
(iii) a plurality of holes configured to line up with the holes of the top plate; and
(iv) two side plates extending away from the bottom surface in a parallel plane to each other, the two side plates comprising a plurality of holes that at least partially align with each other; and
(c) at least one through bolt configured to pass through at least one hole of the top plate and one hole of the bottom plate and to secure the top plate and the bottom plate to each other.

2. The mounting bar connection system according to claim 1, further comprising at least one throughbolt fitted through at least one hole of each of the side plates,
wherein the throughbolt is configured to secure the side plates to an upright arm.

3. The mounting bar connection system according to claim 1, wherein the bottom surface of the top plate and the top surface of the bottom plate are configured to surround a portion of a work platform, and
wherein the throughbolt is configured to secure the receiver assembly to the work platform when passed through at least one hole of the top plate and one hole of the bottom plate while the top plate and bottom plate surround the portion of the work platform.

4. The mounting bar connection system according to claim 1, further comprising:
an upright arm comprising:
(a) an elongated shaft connecting a top end and a bottom end, the top end comprising a mount top tube lock;
(b) a lower mounting plate connected to the bottom end of the elongated shaft and extending away from the bottom end in a perpendicular direction, the lower mounting plate comprising:
(i) at least one hole configured to align with at least one hole of each of the side plates; and
(ii) at least one throughbolt configured to fit through the holes of the lower mounting plate and each of the side plates; and
(c) a top member fitted through the mount top tube lock of the top end of the elongated shaft.

5. The mounting bar connection system according to claim 4, further comprising
a second upright arm comprising:
(a) an elongated shaft connecting a top end and a bottom end, the top end comprising a mount top tube lock; and
(b) a lower mounting plate connected to the bottom end of the elongated shaft and extending away from the bottom end in a perpendicular direction, the lower mounting plate comprising:
(i) at least one hole configured to align with at least one hole of each of the side plates; and
(ii) at least one throughbolt configured to fit through the holes of the lower mounting plate and each of the side plates;
wherein the top member fits through the top lock of the second upright arm.

6. The mounting bar connection system according to claim 4, wherein the upright arm further comprises:
at least one clamping mechanism comprising a hook and an attachment mechanism that secures to a portion of the elongated shaft of the upright arm,
wherein the clamping mechanism is configured to secure the upright arm to a portion of a work platform.

7. The mounting bar connection system according to claim 4, wherein the upright arm further comprises a spigot comprising:
a frame having an outside surface and an inside surface configured to wrap around an outside surface of the top member; and
a threaded fastener configured to secure the frame to the top member.

8. The mounting bar connection system according to claim 1, further comprising:
a truss mounting bracket comprising:
(i) a cylindrical elongate body;
(ii) a first wing extending away from the body, the first wing comprising a hole at the end of the first wing and configured to couple to one of the holes of the side plates of the receiver assembly with a first pin; and
(iii) a clamp configured to secure the cylindrical elongate body to part of a truss.

9. The mounting bar connecting system according to claim 8, wherein the truss mounting bracket further comprises:
a second wing extending away from the body, the second wing comprising a hole at the end of the second wing and configured to couple to one of the holes of the side plates of the receiver assembly with a second pin.

10. The mounting bar connecting system according to claim 8, wherein the truss mounting bracket further comprises:
a second clamp configured to secure the cylindrical elongate body to part of the truss.

11. A mounting bar connection system comprising:
a receiver assembly comprising:
(a) a receiver top plate comprising a top surface, a bottom surface, and a plurality of holes passing through the top plate;
(b) a first receiver bottom plate comprising:
(i) a top surface;
(ii) a bottom surface;
(iii) a plurality of holes configured to line up with the holes of the top plate; and
(iv) a set of two side plates extending away from the bottom surface of the first receiver bottom plate in a parallel plane to each other, the set of two side plates comprising a plurality of holes that at least partially align with each other;
(c) a second receiver bottom plate comprising:
(i) a top surface;
(ii) a bottom surface;
(iii) a plurality of holes configured to line up with the holes of the top plate; and
(iv) a set of two side plates extending away from the bottom surface of the second receiver bottom plate in a parallel plane to each other, the set of two side plates comprising a plurality of holes that at least partially align with each other; and
(d) at least two through bolts configured to individually pass through at least one hole of the top plate and one hole of the first bottom plate and the second bottom plate.

12. The mounting bar connection system according to claim 11, further comprising at least one throughbolt fitted through at least one hole of each of the side plates of the first receiver,
wherein the throughbolt is configured to secure the side plates of the first receiver to an upright arm.

13. The mounting bar connection system according to claim 11, wherein the bottom surface of the top plate of the first receiver and the top surface of the bottom plate of the first receiver are configured to surround a portion of a work platform, and
wherein the throughbolt is configured to secure the first receiver assembly to the work platform when passed through at least one hole of the top plate and one hole of the bottom plate while the top plate and bottom plate surround the portion of the work platform.

14. The mounting bar connection system according to claim 11, further comprising:
an upright arm comprising:
(a) an elongated shaft connecting a top end and a bottom end, the top end comprising a mount top tube lock;
(b) a lower mounting plate connected to the bottom end of the elongated shaft and extending away from the bottom end in a perpendicular direction, the lower mounting plate comprising:
(i) at least one hole configured to align with at least one hole of each of the side plates; and
(ii) at least one throughbolt configured to fit through the holes of the lower mounting plate and each of the side plates of one of the first receiver bottom plate or the second receiver bottom plate; and
(c) a top member fitted through the mount top tube lock of the top end of the elongated shaft.

15. The mounting bar connection system according to claim 14, further comprising
a second upright arm comprising:
(a) an elongated shaft connecting a top end and a bottom end, the top end comprising a mount top tube lock; and
(b) a lower mounting plate connected to the bottom end of the elongated shaft and extending away from the bottom end in a perpendicular direction, the lower mounting plate comprising:
(i) at least one hole configured to align with at least one hole of each of the side plates; and
(ii) at least one throughbolt configured to fit through the holes of the lower mounting plate and each of the side plates;
wherein the top member fits through the top lock of the second upright arm.

16. The mounting bar connection system according to claim 14, wherein the upright arm further comprises:
at least one clamping mechanism comprising a hook and an attachment mechanism that secures to a portion of the elongated shaft of the upright arm,
wherein the clamping mechanism is configured to secure the upright arm to a portion of a work platform.

17. The mounting bar connection system according to claim 14, wherein the upright arm further comprises a spigot comprising:
a frame having an outside surface and an inside surface configured to wrap around an outside surface of the top member; and
a threaded fastener configured to secure the frame to the top member.

18. The mounting bar connection system according to claim 11, further comprising:
a truss mounting bracket comprising:
(i) a cylindrical elongate body;
(ii) a first wing extending away from the body, the first wing comprising a hole at the end of the first wing and configured to couple to one of the holes of the side plates of the receiver assembly with a first pin; and
(iii) a clamp configured to secure the cylindrical elongate body to part of a truss.

19. The mounting bar connection system according to claim 18, wherein the truss mounting bracket further comprises:
a second wing extending away from the body, the second wing comprising a hole at the end of the second wing and configured to couple to one of the holes of the side plates of the receiver assembly with a second pin.

20. The mounting bar connection system according to claim 18, wherein the truss mounting bracket further comprises:
a second clamp configured to secure the cylindrical elongate body to part of the truss.
